(19) United States
(12) Patent Application Publication
(10) Pub. No.: US 2006/0181199 A1
(43) Pub. Date: Aug. 17, 2006

(54) Organic light emitting device comprising multilayer cathode

(76) Inventors: Tae-Woo Lee, Seoul (KR); Yu-Jin Kim, Suwon-si (KR); Sang-Hoon Park, Seongnam-si (KR); In-Nam Kang, Ansan-si (KR)

Correspondence Address: Robert E. Bushnell, Suite 300, 1522 K Street, N.W., Washington, DC, 20005-1202, US

(21) Appl. No.: 11/354,869

(22) Filed: Feb. 16, 2006

(30) Foreign Application Priority Data
Feb. 16, 2005 (KR) 10-2005-0012913

(51) Int. Cl. H01L 51/50; H05B 33/26

(52) U.S. Cl. 313/503; 313/504; 313/506; 428/690; 428/917

(57) ABSTRACT

An organic light emitting device that includes a cathode, an anode and an organic layer arranged between the cathode and the anode, wherein the cathode includes at least one metal layer and at least one inorganic electrode layer alternately arranged, the cathode includes at least three layers. The organic light emitting device has excellent luminous efficiency, luminance, color coordinate characteristic, power efficiency and an increased lifetime while preventing the cathode electrode from diffusing into the organic emitting layer.

### CLAIM OF PRIORITY

This application makes reference to, incorporates the same herein, and claims all benefits accruing under 35 U.S.C.§119 from an application for ORGANIC ELECTROLUMINESCENCE DEVICE COMPRISING MULTILAYER CATHODE earlier filed in the Korean Intellectual Property Office on 16 Feb. 2005 and there duly assigned Serial No. 10-2005-0012913.

### BACKGROUND OF THE INVENTION

1. Field of the Invention

The present invention relates to an organic light emitting device, and more particularly, to an organic light emitting device which has excellent luminous efficiency, luminance, color coordinate characteristic, power efficiency and an increased lifetime by using a multilayered cathode.

2. Description of the Related Art

Organic light emitting devices (OLEDs) are self-emissive devices using a phenomenon that when electrical current is applied to a fluorescent or phosphorescent organic layer, electrons and holes are combined in the organic layer to emit light. OLEDs have advantages such as being light in weight, having simple constitutional elements, easy to fabricate, having high image quality and having high color purity. Further, OLEDs can realize moving pictures perfectly and can be operated at low power consumption. Thus, vigorous research is being conducted on OLEDs.

An OLED has an anode electrode layered on a substrate and an hole injection layer (HIL) and an hole transport layer (HTL) as hole-related layers sequentially layered on the anode electrode, an emitting layer (EML) layered on the HTL, and a cathode electrode layered on the EML.

Many attempts have been made to increase luminous efficiency or power efficiency and lifetime of the OLED by improving characteristics of the cathode electrode. With regard to this, cathode electrodes having a multilayer structure or having various interlayers have been suggested.

For example, U.S. Pat. No. 6,255,774 B1 to Pichler describes a multilayer cathode having a first electrode having a work function of 3.7 eV or less and a thickness of 5 nm or less and a second electrode. U.S. Pat. Nos. 6,558,817, 5,739,635, and 6,541,790 B1 and EP 1,336,995 A2 describe cathode electrodes including various interlayers. However, when devices are driven while controlling injection of electrical current into these cathodes, the cathode electrodes diffuse into EMLs with time. As a result, the luminous efficiency and lifetime of the devices decrease. What is therefore needed is an improved design for an OLED using a multi layered cathode that limits or prevents the cathode electrode from diffusing into the EMLs.

### SUMMARY OF THE INVENTION

It is therefore an object of the present invention to provide an improved design for an organic light emitting device.

It is further an object of the present invention to provide an improved design for a multi layered cathode electrode in an OLED.

It is yet an object of the present invention to provide a design for an OLED that includes a multi layered cathode where, over time, the cathode electrode does not diffuse into the emitting layers of the device.

It is still an object of the present invention to provide an OLED having excellent luminous efficiency, improved luminance, improved color coordinate characteristic, improved power efficiency and an increased lifetime by controlling injection of electrical current into a cathode electrode and preventing diffusion of the cathode electrode into an emitting layer (EML).

According to an aspect of the present invention, there is provided an OLED that includes a cathode, an anode and an organic layer arranged between the cathode and the anode, wherein the cathode includes at least one metal layer and at least one inorganic electrode layer alternately arranged, the cathode having at least three layers.

The at least one metal layer can have a work function of 2.0-7.0 eV. The at least one metal layer can be one or more of Li, Cs, Ca, Ba, Mg, Al, Ag and Au. The at least one metal layer can have a thickness between 0.2 and 500 nm. The at least one inorganic electrode layer can include one or more of a metal oxide, a metal halide, a metal nitride and a metal peroxide. The at least one inorganic electrode layer can include one of BaF₂, LiF, CsF, BaF₂, MgF₂, Al₂O₃, MgO, and LiO₂. The at least one inorganic electrode layer can have a thickness between 0.1 and 30 nm.

The cathode can be a stacked structure in which one of said at least one inorganic electrode layers is arranged on the organic layer, one of said at least one metal layer is arranged on the one of said at least one inorganic electrode layer, and another of said at least one inorganic electrode layer is arranged on the one of the at least one metal layer.

The cathode can be a stacked structure of at least four layers, the cathode including one of the at least one inorganic electrode layer arranged on the organic layer, one of said at least one metal layer arranged on the one of the at least one inorganic electrode layer, another of the at least one inorganic electrode layer is arranged on the one of the at least one metal layer, and another of the at least one metal layer is arranged on the another of the at least one inorganic electrode layer.

The multilayer cathode can have a stacked structure of at least four layers where one of the at least one inorganic electrode layer is arranged on the organic layer, one of the at least one metal layer is arranged on the one of the at least one inorganic electrode layer, another of the at least one inorganic electrode layer is arranged on the one of the at least one metal layer, and another of the at least one metal layer is arranged on the another of the at least one inorganic electrode layer.

The one of the at least one metal layer can have a lower work function than that of the another of the at least one metal layer. The one of the at least one metal layer can have a work function of 3.5 eV or less. The one of the at least one metal layer can have a thickness between 0.2 and 100 nm and the another of the at least one metal layer has a thickness between 5 and 500 nm.

### BRIEF DESCRIPTION OF THE DRAWINGS

A more complete appreciation of the invention and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic cross-sectional view of an OLED;

FIG. 2 is a schematic cross-sectional view of an OLED having a multilayer cathode;

FIG. 3 is a schematic cross-sectional view of an OLED according to an embodiment of the present invention;

FIG. 4 is a graph of luminance vs. luminous efficiency for an OLED according to an embodiment of the present invention together with that of another OLED;

FIG. 5 is a graph of current density vs. luminous efficiency for an OLED according to an embodiment of the present invention together with that of another OLED;

FIG. 6 is a graph of current density vs. power efficiency for an OLED according to an embodiment of the present invention together with that of another OLED; and

FIG. 7 is a graph of voltage vs. luminous efficiency and power efficiency for an OLED according to an embodiment of the present invention.

### DETAILED DESCRIPTION OF THE INVENTION

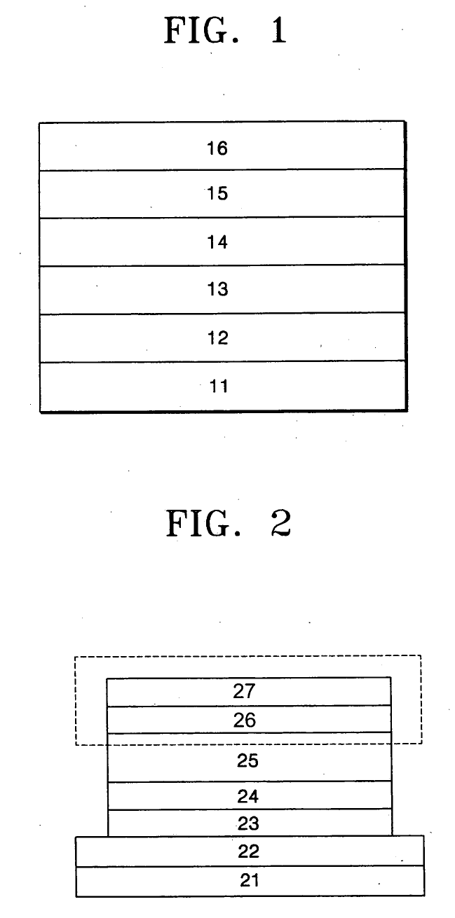

Turning now to the figures, FIG. 1 is a schematic cross-sectional view of an organic light emitting device. Referring to FIG. 1, the organic light emitting device (OLED) has a structure in which an anode electrode 12 is layered on a substrate 11 and a hole injection layer (HIL) 13 and a hole transport layer (HTL) 14 as hole-related layers are sequentially layered on the anode electrode 12, an emitting layer (EML) 15 is layered on the HTL 14, and a cathode electrode 16 is layered on the EML 15.

Many attempts have been made to increase luminous efficiency or power efficiency and lifetime of the OLED by improving characteristics of the cathode electrode 16. With regard to this, cathode electrodes can be a multilayered structure or can have various interlayers.

For example, FIG. 2 illustrates an OLED having a multilayer cathode. The OLED of FIG. 2 includes a substrate 21, an anode 22 located on the substrate 21, an HIL 23 located on anode 22, an HTL 24 on HIL 23, an EML 25 on HTL 24 and the multi-layered cathode on the EML 25. In FIG. 2, the cathode includes a first electrode 26 having a work function of 3.7 eV or less and a thickness of 5 nm or less and a second electrode 27 on top of the first electrode 26. However, when such a device is driven while controlling injection of electrical current into the cathode, the cathode electrode diffuse into EMLs with time. Thus, the luminous efficiency and lifetime of the device of FIG. 2 decreases.

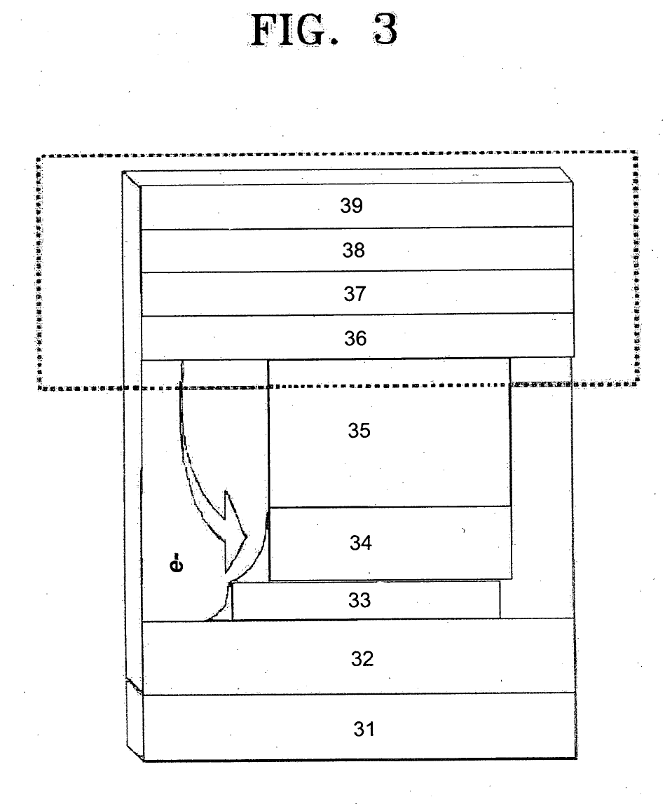

Turning now to FIG. 3, FIG. 3 is a schematic cross-sectional view of an OLED according to an embodiment of the present invention. Referring to FIG. 3, the cathode of the OLED has a stacked structure of at least three layers (four shown in FIG. 3). In FIG. 3, the cathode is shown to have an inorganic electrode layer 36, a first metal layer 37, a second inorganic electrode layer 38, and a second metal layer 39 are sequentially stacked upon one another. The first inorganic electrode layer 36 functions as an electron injection layer and the second inorganic electrode layer 38 prevents diffusion of the second metal layer 39 into an emitting layer 35. Reference numerals 31, 32, 33, 34, and 35 respectively denote an anode electrode, an HIL, an HTL, an emission region, and an emitting layer.

In the OLED of FIG. 2, the cathode metal layer diffuses into an organic layer, thus decreasing luminous efficiency and lifetime of the device. An OLED according to an embodiment of the present invention includes a multi layered cathode, where at least one layer of the cathode is an inorganic electrode layer that serves to prevent the diffusion of a cathode metal electrode into an organic layer. In other words, the inorganic electrode layer of a cathode electrode functions as a barrier that prevents diffusion.

The cathode metal layer used in an embodiment of the present invention may be made of a metal having a work function between 2.0 and 7.0 eV. There is no suitable metal that has a work function less than 2.0 eV, and if there were any, such a metal would induce an excess injection of electrons and would be unstable to oxygen or moisture. Similarly, there is no suitable metal having a work function greater than 7.0 eV, and if there were any, such a metal would have too high a work function and thus, electrons could not be easily injected into the metal layer. Examples of metals having a work function between 2.0 and 7.0 eV include, but are not limited to, Li, Cs, Ca, Ba, Mg, Al, Ag, Au, and alloys thereof.

The metal layer may have a thickness between 0.2 and 500 nm. If the thickness of the metal layer is less than 0.2 nm, the metal layer cannot function as an electrode. If the thickness of the metal layer is greater than 500 nm, the characteristics of the device are not further improved.

The inorganic electrode layer used in an embodiment of the present invention maybe made of a metal oxide, a metal halide, a metal nitride, a metal peroxide or a mixture thereof. Specific examples of materials that can be used in the inorganic electrode layer include, but are not limited to LiF, CsF, BaF₂, MgF₂, Al₂O₃, MgO, LiO₂, and mixtures thereof.

The inorganic electrode layer may have a thickness between 0.1 and 30 nm. If the thickness of the inorganic electrode layer is less than 0.1 nm, the inorganic electrode layer cannot function as a diffusion barrier. If the thickness of the inorganic electrode layer is greater than 30 nm, a conductivity through the inorganic electrode layer decreases preventing the cathode from properly functioning.

Although the OLED with having a cathode having the stacked structure of four layers, i.e., in which the first inorganic electrode layer 36, the first metal layer 37, the second inorganic electrode layer 38, and the second metal layer 39 are sequentially stacked upon one another, is illustrated in FIG. 3, the present invention is not limited to this structure. For example, an OLED according to another embodiment of the present invention can have a cathode having a stacked structure of just three layers. One example of such a three layered cathode of the present invention would be an inorganic electrode layer being stacked on the organic layer, and a metal layer being stacked on the inorganic electrode layer and a second inorganic electrode layer being stacked on the metal layer. Another example of a three layered cathode according to the present invention would be a metal layer on the EML, an inorganic electrode layer on the metal layer and then a second metal layer on the inorganic electrode layer.

When the cathode has at least two inorganic electrode layers, a material of a first inorganic electrode layer can be the same as or different from that of a second inorganic electrode layer. When the device has at least two metal layers, a material of a first metal layer can be the same as or different from that of a second metal layer.

When the device has at least two metal layers and the material of the first metal layer is different from that of the second metal layer, the first metal layer being closer to the emitting layer than the second metal layer, it is preferable that the first metal layer has a lower work function than that of the second metal layer since the first metal layer joins to an organic layer and determines a difference in the energy level between the metal work function and the lowest unoccupied molecular orbital (LUMO) of the organic layer, i.e., a barrier for electron injection.

It is preferable that the first metal layer have a work function of 3.5 eV or less, since in most cases, LUMO of an organic material has a work function of 3.5 eV or less and as the work function of the metal decreases, the electrons can be easily injected into the organic layer.

The first metal layer can have a thickness between 0.2 and 100 nm and the second metal layer can have a thickness between 5 and 500 nm. If the thickness of the first metal layer is less than 0.2 nm, the first metal layer cannot function as an electrode. If the thickness of the first metal layer is greater than 100 nm, a second or a third metal layer cannot efficiently function as an electrode. If the thickness of the second metal layer is less than 5 nm, a surface conductivity decreases. If the thickness of the second metal layer is greater than 500 nm, the characteristics of the device are not further improved.

The structure of an OLED according to an embodiment of the present invention will now be described in more detail. The OLED can be produced using a high molecular weight emitting layer (EML) or a low molecular weight EML. The OLED using the high molecular weight EML includes an anode electrode formed on a substrate, an HIL formed on the anode electrode, an HTL formed on the HIL, an EML formed on the HTL, an electron transport layer (ETL) formed on the EML, an electron injection layer (EIL) formed on the ETL, and a cathode electrode formed on the EIL.

The substrate can be a glass substrate or a transparent plastic substrate, which have excellent transparency, surface smoothness, easy handling, and excellent waterproofness.

When the OLED is a front emission type device, the anode electrode formed on the substrate is a reflective metal layer. When the OLED is a rear emission type device, the anode electrode can be made of a transparent and highly conductive material, such as indium tin oxide (ITO), indium zinc oxide (IZO), tin oxide (SnO₂), zinc oxide (ZnO), or a mixture thereof.

When a high molecular weight EML is used, the HIL can have a thickness between 50 and 1500 Å. If the thickness of the HIL is less than 50 Å, the hole injection property is poor. If the thickness of the HIL is greater than 1500 Å, the hole injection ability is not further improved and a driving voltage can increase according to a material of the HIL, which is undesirable. The HTL can have a thickness between 50 and 1500 Å. If the thickness of the HTL is less than 50 Å, the hole transport property is poor. If the thickness of the HTL is greater than 1500 Å, a driving voltage increases, which is undesirable. In the OLED using the high molecular weight EML, a phosphorescent material and a fluorescent material can be used in the EML. An EIL can be selectively formed on the EML. The EIL can be made of, for example ionomer (for example, sodium sulfonated polystyrene), a metal halide (for example, LiF, CsF, or BaF₂), or a metal oxide (for example, Al₂O₃). A multilayer cathode according to an embodiment of the present invention is formed on the EML (when the device does not include an EIL) or on the EIL (when the device includes an EIL).

An OLED using the low molecular weight EML includes an anode electrode formed on a substrate, an HIL formed on the anode electrode, an HTL formed on the HIL, an EML formed on the HTL, an ETL formed on the EML, an EIL formed on the ETL, and a cathode electrode formed on the EIL. The OLED using the low molecular weight EML can use the same substrate and anode electrode as the high molecular weight OLED.

When a low molecular weight EML is used, the HIL can have a thickness between 50 and 1500 Å. If the thickness of the HIL is less than 50 Å, a hole injection property is poor. If the thickness of the HIL is greater than 1500 Å, the driving voltage increases, which is undesirable.

When a high molecular weight EML is used, the HTL can have a thickness of 50-1500 Å. If the thickness of the HTL is less than 50 Å, a hole transport property is poor. If the thickness of the HTL is greater than 1500 Å, a hole injection ability is not further improved and the driving voltage can increase according to a material of the HIL, which is undesirable.

In the OLED using the low molecular weight EML, a red light-emitting material in a red light region (R), a green light-emitting material in a green light region (G), and a blue light-emitting material in a blue light region are respectively patterned to obtain EMLs which correspond to pixel regions. Each of the light emitting materials can be a mixture of at least two host materials.

The EML can have a thickness between 100 and 2000 Å, and preferably between 300 and 400 Å. If the thickness of the EML is less than 100 Å, luminous efficiency and lifetime decreases. If the thickness of the EML is greater 2000 Å, a driving voltage increases, which is undesirable.

In the OLED using the low molecular weight EML, the ETL is formed on the EML. The ETL can be made of, for example, Alq3. The ETL can have a thickness between 50 and 600 Å. If the thickness of the ETL is less than 50 Å, the lifetime decreases. If the thickness of the ETL is greater than 600 Å, a driving voltage increases, which is undesirable.

An EIL can be selectively formed on the ETL. The EIL can be made of, for example, LiF, NaCl, CsF, Li₂O, BaO, or Liq. The EIL can have a thickness between 1 and 100 Å. If the thickness of the EIL is less than 1 Å, the EIL cannot efficiently finction, and thus a driving voltage increases. If the thickness of the EIL is greater than 100 Å, the EIL functions as an insulating layer, and thus the driving voltage increases.

Essentially, the structure of the OLED having a low molecular weight EML is similar to an OLED having a high molecular weight EML. Both designs can include an HIL, an HTL, an EML, an ETL and an EIL. Further, the multi-layer cathode of the present invention can be applied to each of the high molecular weight OLED and the low molecular weight OLED.

Next, a multilayer cathode according to an embodiment of the present invention is formed on the ETL. In forming the cathode, an inorganic electrode layer can not be directly formed on an EIL layer.

An OLED according to an embodiment of the present invention can be manufactured as follows. First, a material for forming an anode electrode is coated on a substrate. An insulating layer (or pixel define layer(PDL)) defining a pixel region can be formed on the anode electrode.

Then, an HIL, which is an organic layer, is coated on the resultant structure. The HIL can be formed on the anode electrode using a method, such as a vacuum thermal deposition method or a spin coating method.

Then, an HTL can be optionally formed on the HIL using a vacuum thermal deposition method or a spin coating method, etc. The EML can be formed on the HIL (when the device does not include an HTL) or on the HTL (when the device does include an HTL). The EML can be formed using a method such as vacuum deposition, inkjet printing, laser induced thermal imaging, photolithography, etc.

Subsequently, an ETL and an EIL can be optionally formed on the EML using a vacuum thermal deposition method or a spin coating method. Then, a multilayer cathode according to an embodiment of the present invention is coated on the resultant structure using a vacuum thermal deposition method. The resultant structure is then encapsulated.

The present invention will be described in more detail with reference to the following examples. It is to be understood that these examples are given for the purpose of illustration and are not intended to limit the scope of the invention.

### EXAMPLE 1

An ITO glass substrate with a surface resistance of 15 Ω/cm² (1200 Å) (available from Samsung Corning Corporation) was cut into a size of 50 mm×50 mm×0.7 mm and sonicated in pure water and isopropyl alcohol, respectively, for 5 minutes and cleaned with UV light and ozone, respectively, for 30 minutes. Then, Poly(3,4-ethylenedioxythiophene) poly(styrenesulfonate) (PEDOT/PSS) (Baytron P AI4083, available from Bayer) was coated on the ITO glass substrate to a thickness of 50 nm at 2,000 rpm and the coated substrate was heated at 200° C. for 10 minutes on a hot plate.

A hole transport material, poly(9,9-dioctylfluorene-co-bis-N,N′-(4-butylphenyl)-bis-N,N′-phenyl-1,4-phenylenediamine (PFB, available from Dow Chemical Company) was spin coated on the resultant HIL to form an HTL having a thickness of 10 nm. Then, the resultant product was heated at 220° C. for 1 hour under nitrogen atmosphere.

Subsequently, poly(2′,3′,6′,7′-tetraoctyloxy spirofluorene-co-N-(4′-ethylhexyloxy)-phenoxazine)(TS-9), which is apolyspirofluorene-based blue light-emitting material having a weight average molecular weight of 1,500,000, was dissolved in xylene in a concentration of 1.0% by weight. The resultant solution was transferred onto an HTL using a micropipette and spin coated, and then the resultant structure was heated at 200° C. for 30 minutes.

Then, BaF₂ was vacuum deposited to a thickness of 5 nm on the EML, and Ca was vacuum deposited to a thickness of 3.3 nm on the BaF₂ layer, BaF₂ was again vacuum deposited to a thickness of 0.5 nm on the Ca layer, and then Al was vacuum deposited to a thickness of 300 nm on the BaF₂ layer. The resultant structure was encapsulated to manufacture an OLED according to an embodiment of the present invention.

### Comparative Example

An OLED was manufactured in the same manner as in Example 1, except that after BaF₂/Ca was vacuum deposited to a thickness of 5 nm on the EML, Ca and Al were vacuum deposited to thicknesses of 3.3 nm and 300 nm, respectively.

Performance Test

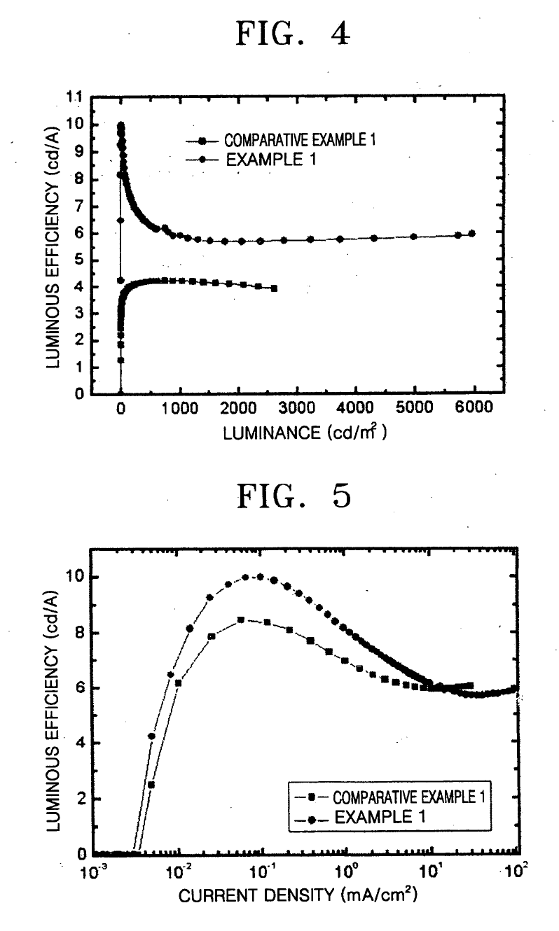

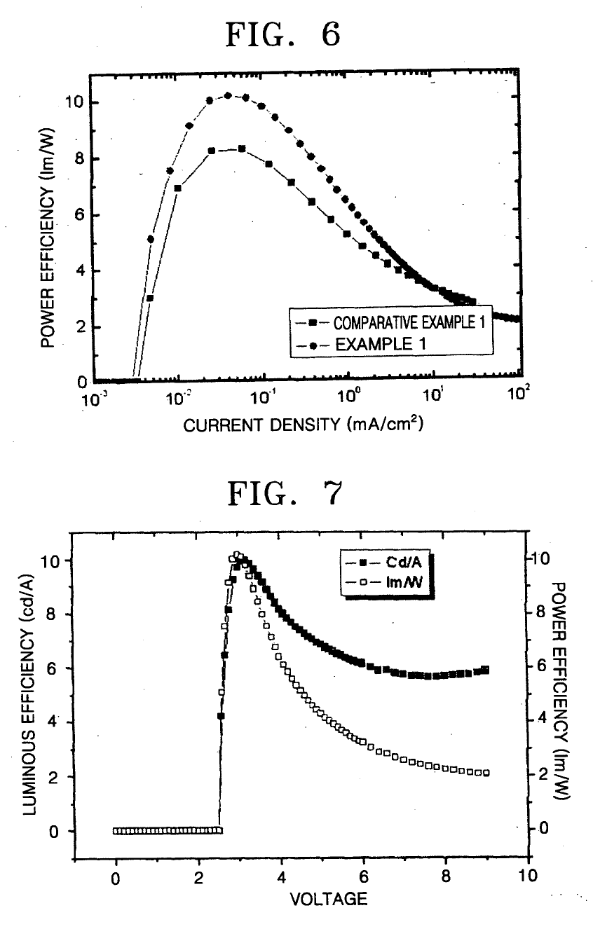

FIG. 4 is a graph of luminance vs. luminous efficiency for an OLED manufactured in Example 1 and an OLED manufactured in the Comparative Example. FIG. 5 is a graph of current density vs. luminous efficiency for an OLED manufactured in Example 1 and an OLED manufactured in the Comparative Example. FIG. 6 is a graph of current density vs. power efficiency for an OLED manufactured in Example 1 and an OLED manufactured in the Comparative Example. FIG. 7 is a graph of voltage vs. luminous efficiency and power efficiency for an OLED manufactured in Example 1.

Referring to FIG. 4, the OLED manufactured in Example 1 according to an embodiment of the present invention had higher luminous efficiency than the OLED manufactured in the Comparative Example, as the luminance increased.

Referring to FIGS. 5 and 6, the OLED manufactured in Example 1 according to an embodiment of the present invention had higher luminous efficiency higher power efficiency by 20% than the OLED made in the Comparative example, at a given current density.

Referring to FIG. 7, the OLED manufactured in Example 1 according to an embodiment of the present invention had high luminous efficiency and power efficiency at a given voltage. A power efficiency of 10 lm/W corresponds to the highest power efficiency in an OLED using a single layer of blue light emitting polymer.

An OLED according to the present invention has excellent luminous efficiency, luminance, color coordinate characteristic and power efficiency and an increased lifetime by controlling injection of electrical current into a cathode electrode and preventing diffusion of the cathode electrode into an EML.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An organic light emitting device (OLED), comprising:
a cathode;
an anode; and
an organic layer arranged between the cathode and the anode, wherein the cathode comprises at least one metal layer and at least one inorganic electrode layer alternately arranged, the cathode comprising at least three layers.

2. The OLED of claim 1, wherein the at least one metal layer has a work function in the range of 2.0-7.0 eV.

3. The OLED of claim 1, wherein the at least one metal layer comprises a material selected from the group consisting of Li, Cs, Ca, Ba, Mg, Al, Ag, Au, and an alloy thereof.

4. The OLED of claim 1, wherein the at least one metal layer has a thickness in the range of 0.2-500 nm.

5. The OLED of claim 1, wherein the at least one inorganic electrode layer comprises a material selected from the group consisting of a metal oxide, a metal halide, a metal nitride, a metal peroxide, and a mixture thereof.

6. The OLED of claim 5, wherein the at least one inorganic electrode layer comprises a material selected from the group consisting of BaF₂, LiF, CsF, BaF₂, MgF₂, Al₂O₃, MgO, and LiO₂.

7. The OLED of claim 1, wherein the at least one inorganic electrode layer has a thickness in the range of 0.1-30 nm.

8. The OLED of claim 1, wherein the cathode is a stacked structure in which one of said at least one inorganic electrode layers is arranged on the organic layer, one of said at least one metal layer is arranged on the one of said at least one inorganic electrode layer, and another of said at least one inorganic electrode layer is arranged on the one of the at least one metal layer.

9. The OLED of claim 1, wherein the cathode comprises a stacked structure of at least four layers comprising one of the at least one inorganic electrode layer arranged on the organic layer, one of said at least one metal layer arranged on the one of the at least one inorganic electrode layer, another of the at least one inorganic electrode layer arranged on the one of the at least one metal layer, and another of the at least one metal layer arranged on the another of the at least one inorganic electrode layer.

10. The OLED of claim 1, wherein the multilayer cathode has a stacked structure of at least four layers where one of the at least one inorganic electrode layer is arranged on the organic layer, one of the at least one metal layer is arranged on the one of the at least one inorganic electrode layer, another of the at least one inorganic electrode layer is arranged on the one of the at least one metal layer, and another of the at least one metal layer is arranged on the another of the at least one inorganic electrode layer.

11. The OLED of claim 9, wherein the one of the at least one metal layer has a lower work function than that of the another of the at least one metal layer.

12. The OLED of claim 10, wherein the one of the at least one metal layer has a lower work function than that of the another of the at least one metal layer.

13. The OLED of claim 9, wherein the one of the at least one metal layer has a work function of 3.5 eV or less.

14. The OLED of claim 10, wherein the one of the at least one metal layer has a work function of 3.5 eV or less.

15. The OLED of claim 9, wherein the one of the at least one metal layer has a thickness in the range of 0.2-100 nm and the another of the at least one metal layer has a thickness in the range of 5-500 nm.

16. The OLED of claim 10, wherein the one of the at least one metal layer has a thickness in the range of 0.2-100 nm and the another of the at least one metal layer has a thickness in the range of 5-500 nm.

17. An organic light emitting device (OLED), comprising:
a cathode;
an anode; and
an organic layer arranged between the cathode and the anode, wherein the cathode comprises at least one metal layer and at least one inorganic electrode layer alternately arranged, one of the at least one inorganic electrode layer being adapted to prevent diffusion from one of the at least one metal layer into the organic layer during a lifetime of the OLED, the cathode further comprising at least one of another inorganic electrode layer and another metal layer.

18. The OLED of claim 17, the cathode comprising:
a first of the at least one inorganic electrode layer arranged on the organic layer;
a first of the at least one metal layer arranged on the first of the at least one inorganic electrode layer;
a second of the at least one inorganic electrode layer arranged on the first of the at least one metal layer; and
a second of the at least one metal layer arranged on the second of the at least one inorganic electrode layer.

19. The OLED of claim 18, the second of the at least one inorganic electrode layer being adapted to prevent diffusion from the second of the at least one metal layer into the organic layer.

20. The OLED of claim 17, the cathode comprising:
a first of the at least one metal layer arranged on the organic layer;
a first of the at least one inorganic electrode layer arranged on the first of the at least one metal layer; and
a second of the at least one metal layer arranged on the first of the at least one inorganic electrode layer, the first of the at least one inorganic electrode layer being adapted to prevent diffusion from the second of the at least one metal layer into the organic layer.
